(19) United States
(12) Patent Application Publication
(10) Pub. No.: US 2012/0175696 A1
(43) Pub. Date: Jul. 12, 2012

(54) MULTILAYER FLOATING GATE FIELD-EFFECT TRANSISTOR (FET) DEVICES AND RELATED METHODS

(75) Inventors: Paul D. Franzon, New Hill, NC (US); Neil Di Spigna, Durham, NC (US); Daniel Schinke, Hillsboro, OR (US)

(73) Assignee: NORTH CAROLINA STATE UNIVERSITY, Raleigh, NC (US)

(21) Appl. No.: 13/292,717

(22) Filed: Nov. 9, 2011

Related U.S. Application Data
(60) Provisional application No. 61/411,596, filed on Nov. 9, 2010.

(51) Int. Cl. H01L 29/788; H01L 21/336; B82Y 99/00

(52) U.S. Cl. 257/316; 438/257; 257/E29.3; 257/E21.422; 977/943

(57) ABSTRACT

Multilayer floating gate field-effect transistor (FET) devices and related methods are provided. A multilayer floating gate FET device can include a first floating gate separated via a first dielectric layer from a channel of the device and a second floating gate separated via a second dielectric layer from the first floating gate. The second dielectric layer between the first floating gate and the second floating gate permits a redistribution of charge between the first and second floating gates from one of the floating gates to the other when under the influence of a first electrical field from a first voltage. In some embodiments, a redistribution of charge between the first and second floating gates with electrons being supplied through a channel to the first and second floating gates can occur when under the influence of a second electrical field from a second voltage that is greater than the first voltage.

### RELATED APPLICATIONS

The presently disclosed subject matter claims the benefit of and priority to U.S. Provisional Patent Application Ser. No. 61/411,596 filed Nov. 9, 2010; the disclosure of which is incorporated herein by reference in its entirety.

### GOVERNMENT INTEREST

The presently disclosed subject matter was made with U.S. Government support under Grant No. CCF-0811582 awarded by National Science Foundation (NSF). Thus, the U.S. Government has certain rights in the presently disclosed subject matter.

### TECHNICAL FIELD

The subject matter disclosed herein relates to field-effect transistors (FETs) and related methods. More particularly, the presently disclosed subject matter relates to multilayer floating gate FET devices and related methods.

### BACKGROUND

Dynamic random-access memory (DRAM) is a type of random-access memory that stores each bit of data in a separate capacitor within an integrated circuit. The capacitor can be either charged or discharged; these two states are taken to represent the two values of a bit, conventionally called 0 and 1. Since capacitors leak charge, the information eventually fades unless the capacitor charge is refreshed periodically.

Non-volatile memory (NVM), in the most basic sense, is computer memory that can retain the stored information even when not powered. Examples of non-volatile memory include read-only memory, flash memory, ferroelectric RAM, most types of magnetic computer storage devices (e.g. hard disks, floppy disks, and magnetic tape), and optical discs. Non-volatile memory is typically used for the task of secondary storage, or long-term persistent storage. The most widely used form of primary storage today is a volatile form of random access memory (RAM), meaning that when the computer is shut down, anything contained in RAM is lost. Unfortunately, most forms of non-volatile memory have limitations that make them unsuitable for use as primary storage. Typically, non-volatile memory either costs more or performs worse than volatile random access memory.

Floating gate devices can be used to create a non-volatile memory device. Nanocrystal floating gate devices have drawn much attention in the non-volatile memory market. Compared to continuous floating gate devices of equivalent dimensions, they are less susceptible to stress induced leakage current (SILC) due to the discrete nature of the storage elements. This allows thinning of the oxide, which results in more efficient charge transfer. The potential benefits are higher programming (erasing) speed, and/or lower programming (erasing) voltage, with a comparable retention time to the continuous floating gate devices. In addition, operational voltage and power consumption are reduced. The thinner oxide also results in an increased gate capacitance, which reduces the device susceptance to drain induced barrier lowering (DIBL). This improves scalability of the nanocrystal floating gate devices compared to its counterpart.

The devices used in creating dynamic random-access memory usually cannot be used to create non-volatile memory. Similarly, devices used to create non-volatile memory usually cannot be used to create dynamic random-access memory. To date, devices have not been developed that can perform the functions of both dynamic random-access memory and non-volatile memory.

### SUMMARY

It is an object of the presently disclosed subject matter to provide novel FET devices and related methods. More particularly, the presently disclosed subject matter provides multilayer floating gate FET devices and related methods that can redistribute a charge between the floating gates from one of the floating gates to another when under the influence of a first electrical field from a first voltage.

An object of the presently disclosed subject matter having been stated hereinabove, and which is achieved in whole or in part by the presently disclosed subject matter, other objects will become evident as the description proceeds when taken in connection with the accompanying drawings as best described hereinbelow.

### BRIEF DESCRIPTION OF THE DRAWINGS

A full and enabling disclosure of the present subject matter including the best mode thereof to one of ordinary skill in the art is set forth more particularly in the remainder of the specification, including reference to the accompanying figures, in which:

FIG. 1 illustrates a vertical cross-sectional schematic view of an embodiment of a multilayered floating gate FET device according to the subject matter disclosed herein;

FIGS. 2A, 2B, 2C illustrates a vertical cross-sectional schematic view of another embodiment of a multilayered floating gate FET device according to the subject matter disclosed herein;

FIG. 3A illustrates a vertical cross-sectional schematic view of an embodiment of a multilayered floating gate FET device according to the subject matter disclosed herein;

FIG. 3B illustrates a conduction band diagram under flat-band condition corresponding to the embodiment of the floating gate FET device according to FIG. 3A;

FIG. 4 illustrates a vertical cross-sectional schematic view of another embodiment of a multilayered floating gate FET device according to the subject matter disclosed herein;

FIG. 5 illustrates a vertical cross-sectional schematic view of a further embodiment of a multilayered floating gate FET device according to the subject matter disclosed herein;

FIGS. 6A and 6B illustrate conduction band diagrams of the embodiment of the multilayered floating gate FET device according to FIG. 3A under low stress of 4V in FIG. 6A and −4V in FIG. 6B;

FIGS. 7A and 7B illustrate graphs of drain current of the embodiment of the multilayered floating gate FET device according to FIG. 3A before and after a voltage pulse of ±4 V on a linear scale in FIG. 7A and a logarithmic scale in FIG. 7B;

FIGS. 8A and 8B illustrate graphs of retention time results for the embodiment of the multilayered floating gate FET device according to FIG. 3A for a control gate bias of 0 V after the initial voltage pulse for ΔV_{T} in FIG. 8A and Δ(ΔV_{T}) in FIG. 8B according to the subject matter disclosed herein;

FIGS. 9A and 9B illustrate graphs of conduction band diagrams of the embodiment of the multilayered floating gate FET device according to FIG. 3A under high stress of an embodiment of a program mode using 13 V in FIG. 9A and under high stress of an embodiment of a erase mode using −13 V in FIG. 9B;

FIGS. 10A and 10B illustrate ΔV_{T} of the embodiment of the multilayered floating gate FET device according to FIG. 3A for programming the device for 100 μs in FIG. 10A and erasing the device for 10 ms in FIG. 10B;

FIGS. 11A and 11B illustrate graphs of drain current of the embodiment of the multilayered floating gate FET device according to FIG. 3A after program and erase operation on a linear in FIG. 11A and on a logarithmic scale in FIG. 11B;

FIGS. 12A, 12B, and 12C illustrate embodiments of circuit topologies that permit rapidly reprogrammable interconnect topologies by using embodiments of multilayered floating gate FET devices according to the subject matter disclosed herein for an embodiment of a switch box in FIG. 12A, for an embodiment of an output of a connection block in FIG. 12B, and for an embodiment of an input of a connection block in FIG. 12C;

FIG. 13 illustrates a schematic diagram of a hybrid DRAM/Flash memory architecture using the multilayered floating gate FET devices according to the subject matter disclosed herein; and

FIG. 14 illustrates embodiments of circuit topologies for an embodiment of a main memory using multilayered floating gate FET devices according to the subject matter disclosed herein.

### DETAILED DESCRIPTION

Reference will now be made in detail to possible aspects or embodiments of the subject matter herein, one or more examples of which are shown in the figures. Each example is provided to explain the subject matter and not as a limitation. In fact, features illustrated or described as part of one embodiment can be used in another embodiment to yield still a further embodiment. It is intended that the subject matter disclosed and envisioned herein covers such modifications and variations.

The terminology used herein is for the purpose of describing particular embodiments only and is not intended to be limiting of the subject matter disclosed herein. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the presently disclosed subject matter has been presented for purposes of illustration and description, but is not intended to be exhaustive or limited to the subject matter in the form disclosed. Many modifications and variations will be apparent to those of ordinary skill in the art without departing from the scope and spirit of the subject matter disclosed herein. The embodiments were chosen and described herein in order to best explain the principles of the subject matter disclosed herein and it's practical application, and to enable others of ordinary skill in the art to understand the subject matter disclosed herein for various embodiments with various modifications as are suited to the particular use contemplated.

The present subject matter provides a multilayer floating gate field-effect transistor (FET) device. For example, the multilayer floating gate FET device can comprise a multilayer floating gate metal-oxide-semiconductor field-effect transistor (MOSFET) device. Two floating gates can each be programmed via a tunneling current. Free charges can be transferred between the two gates to program and/or refresh the multilayer floating gate FET device. This charge redistribution can occur rapidly via a thin dielectric layer such as a thin oxide layer, resulting in one positively and one negatively charged floating gate and can be considered the dynamic (volatile) storage element. Additionally, the floating gates both can also be programmed more slowly through a relative thick oxide due to charge transfer from the channel and can be considered the non-volatile storage element.

For example, a multilayer floating gate field-effect transistor (FET) device can be provide that comprises a first floating gate separated via a first dielectric layer from a channel of the device and a second floating gate separated via a second dielectric layer from the first floating gate. The second dielectric layer between the first floating gate and the second floating gate can permit a redistribution of charge between the first floating gate and the second floating gate from one of the floating gates to the other when under the influence of a first electrical field from a first voltage. Additionally, in some embodiments, the second dielectric layer between the first floating gate and the second floating gate can permit a redistribution of charge between the first floating gate and the second floating gate with electrons supplied through a channel to the first floating gate and the second floating gate when under the influence of a second electrical field from a second voltage with the second voltage being greater than the first voltage. In such embodiments, a third dielectric layer can be provided that separates the second floating gate from a control gate. The control gate can have the first voltage applied thereto so that the first floating gate and the second floating gate operate as a dynamic memory element in response to a first voltage. Furthermore, the control gate can have the first voltage applied thereto so that the first floating gate and the second floating gate operate as a non-volatile memory element in response to a second voltage.

The floating gates can be solid or discontinuous (i.e., discrete). Use of two floating gates and a configuration of the oxides provide the multifunctional properties for the multilayer floating gate FET devices described herein. The multilayer floating gate FET devices described herein may be referred to alternatively below as the “transistor” or the “device” for ease of description purposes.

Many possible applications exist for the multilayer floating gate FET device described herein. One example application is a memory component that may be either dynamic or non-volatile. As such, the multilayer floating gate FET device can be used as either a dynamic random access memory (DRAM) device or a flash memory device within a given implementation. Further, contents stored within one of the respective storage elements can be transferred between the two storage modes/elements rapidly. Another example application is in the field of circuit-based routers to provide rapid on-chip circuit routing. Many other example applications are possible and all are considered within the scope of the present subject matter.

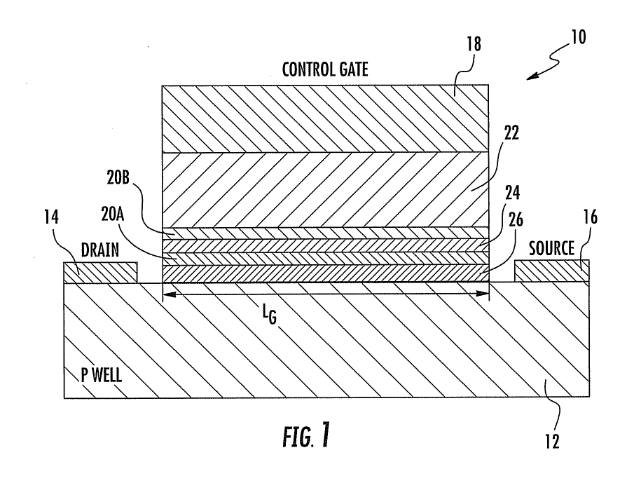

The multilayer floating gate FET devices described herein can comprise multiple floating gates. FIG. 1 shows an embodiment of a multilayer floating gate FET device 10, which can be a multilayer floating gate MOSFET device. Multilayer floating gate FET device 10 can comprise a substrate 12 on which a drain region or terminal 14 and a source region or terminal 16 can reside. A transistor channel can be formed between drain terminal 14 and source terminal 16 in the substrate when a voltage is applied to multilayer floating gate FET device 10. It is understood that drain terminal 14 and source terminal 16 can be reversed so that drain region or terminal 14 can serve as the source region or terminal and source region or terminal 16 can be used as the drain region or terminal. The phrases “drain” and “source” are used for convenience and are interchangeable herein unless otherwise specified.

Multilayer floating gate FET device 10 can also comprise a top control gate 18 through which a voltage can be supplied. Multilayer floating gate FET device 10 can comprise a plurality of floating gates, for example, two floating gates 20A and 20B that can be separated from top control gate 18 by a dielectric layer, such as a thick oxide layer 22. Floating gates 20A and 20B can be separated from each other by a dielectric layer, such as a thin oxide layer 24. Further, floating gates 20A and 20B can be separated from the portion of substrate 12 in which the transistor channel can be formed by a dielectric layer, such as an oxide layer 26. In some embodiments, oxide layer 26 can be considered to have an intermediate thickness as compared to the thicknesses of oxide layer 24 and oxide layer 22. Thicknesses of the example components of multilayer floating gate FET device 10 can vary depending on the use of device 10 and the materials used. For example, a first, or bottom, floating gate 20A and a second, or top, floating gate 20B can each have a thickness of about 3 nm. Oxide layer 22 can, for example, have a thickness of about 18 nm, while oxide layer 24 between floating gates 20A and 20B can have a thickness of about 3.2 nm and oxide layer 26 between first floating gate 20A and substrate 12 can have a thickness of about 4.3 nm. Multilayer floating gate MOSFET device 10 can have a gate length L_{G} that can minimize drain induced barrier lowering (DIBL). As one example, gate length L_{G} can be about 65 nm. Other lengths L_{G} are contemplated.

By using multiple floating gates 20A and 20B, multilayer floating gate FET device 10 can operate as a dynamic memory, a non-volatile memory, and as both a dynamic memory and a non-volatile memory concurrently. For example, multilayer floating gate FET device 10 can be switched rapidly between the two modes of operation. The state/mode of multilayer floating gate FET device 10 can modify a threshold voltage of multilayer floating gate FET device 10, which can be detected through an appropriate external circuit. As additional example applications, beyond providing operational characteristics appropriate for use as a memory, multilayer floating gate FET device 10 can also be used for building on-chip programmable routing networks, for analog signal processing, and for synaptic neural processing.

Relative to conventional technologies, multilayer floating gate FET device 10 can provide reduced programming and erasing voltages and can increase retention of the stored charge (especially in the non-volatile state). Multilayer floating gate FET device 10 can also have increased endurance and increased reliability. Some of these aspects can be achieved by selecting appropriate materials to “band gap” engineer the device (i.e., by choosing metals and relatively thick oxides that maximize the potential barriers within the device for increased charge retention).

Multilayer floating gate FET device 10 can utilize wave-mechanical tunneling, such as field emission based tunneling or Fowler-Nordheim tunneling, to move charge from the channel to floating gates 20A and 20B for the non-volatile memory operation, and direct tunneling to move charge between floating gates 20A and 20B for the dynamic memory operation where endurance and reliability factor into design criteria. Direct tunneling produces less damage to oxide layer 24 and oxide layer 26 than the alternatives of wave-mechanical tunneling and hot carrier injection, especially in low-field stress. The amount of current can be determined by the collective height and widths of the barriers under bias conditions. Band engineering can permit a decrease in the actual height of the barrier for fast programming and an increase in the actual thickness of the barrier for maximizing the retention time (i.e., reducing current leakage due to the tunneling current under low bias conditions). When the device is under higher bias conditions, a high tunneling current can be used to improve programming speed.

In order to optimize these trade-offs, the choice of the materials for floating gates 20A and 20B as well as for oxide layers 22, 24, 26, or insulators, can be considered. High-k insulators, or insulator material, such as hafnium oxide (HfO₂), aluminum oxide (Al₂O₃), zirconium oxide (ZrO₂), hafnium aluminate (HfAlO), and hafnium silicate (HfSiO), have a lower band gap and a higher electron affinity than low-k insulators, or insulator material, such as SiO₂, resulting in a lower barrier especially in the conduction band. In addition, the effective electron mass in the high-k insulator is lower than in its low-k counterpart. Therefore, the tunneling rate of the charges, especially the electrons, can be enhanced. The enhanced tunneling rate can provide fast programming under relatively low applied voltages. A trade-off of the use of such high-k insulators can be that the charge retention time can be shortened because charge leakage through the same insulator can occur more rapidly. Regardless of this charge leaking, high-k insulators can permit physically thicker oxide layers for the same capacitance and can improve the retention-to-program time ratio. Choosing appropriate materials for floating gates 20A and 20B for a given implementation can also assist with optimization of multilayer floating gate FET device 10 for the given implementation.

For purposes of the present description, the term “work function” refers to an energy level required to remove an electron from a solid metal to a point just outside of the solid metal. An example of a high work function metal can include platinum (Pt), gold (Au), or palladium (Pd) with an example energy level range of about 5.1 eV to about 5.65 eV. An example of a low work function metal can include magnesium (Mg) or aluminum (Al) with an example energy level range of about 3.8 eV to about 4.1 eV.

A high work function metal (e.g., with a relatively high energy to remove an electron) creates a deep potential well for the electrons and, thus, the charge leakage can be reduced due to the high barrier. On the other hand, it is also more difficult for the electrons to tunnel through the high barrier in the program mode. As such, the programming voltage or voltage envelope (e.g., a voltage and time duration of the voltage) can be larger to maintain a short programming time. An example of such a programming voltage or voltage envelope can include, for example about 4 or 5 volts (V) for the low work function metal as opposed to about 7 or 8 V for the high work function metal.

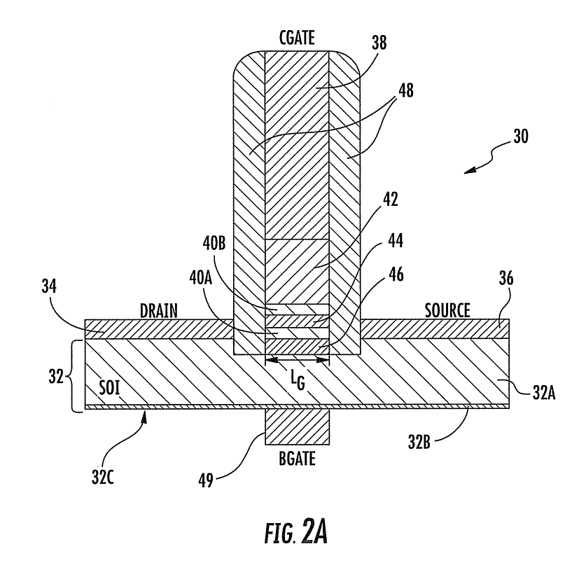

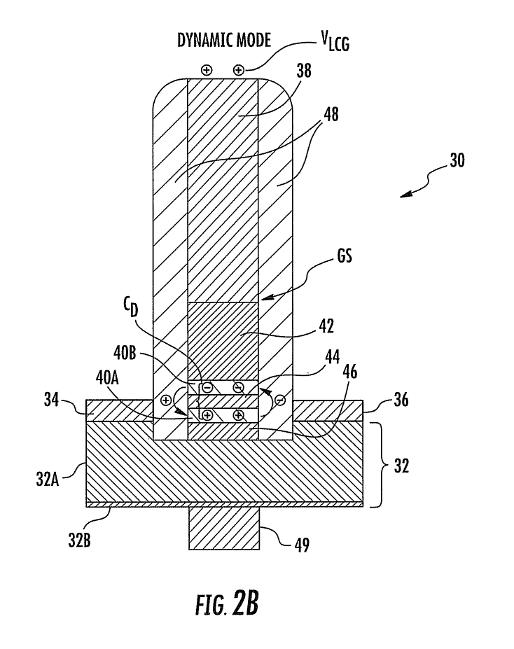

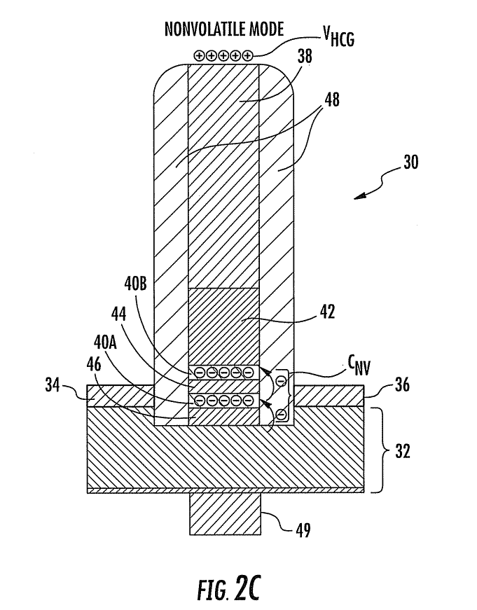

In FIG. 2A, another embodiment of a multilayer floating gate FET device, generally designated 30, is provided. Multilayer floating gate FET device 30 can be a multilayer floating gate MOSFET device. Multilayer floating gate FET device 30 can be a silicon on insulator (SOI) device, for example. Multilayer floating gate FET device 30 can comprise a substrate 32 comprising a substrate body 32A of silicon and a back gate oxide layer 32B. A drain region 34 and a source region 36 can reside on substrate body 32A. A transistor channel can be formed between drain 34 and source 36 in substrate body 32A when a voltage is applied to multilayer floating gate FET device 30. Multilayer floating gate FET device 30 can also comprise a top control gate 38 through which a voltage can be supplied. Multilayer floating gate FET device 30 can comprise a plurality of floating gates, for example, two floating gates 40A and 40B that can be separated from top control gate 38 by a dielectric layer, such as a thick oxide layer 42. First, or bottom, floating gate 40A and second, or top, floating gate 40B can be separated from each other by a dielectric layer, such as a thin oxide layer 44. Further, floating gates 40A and 40B can be separated from the portion of substrate 32 in which the transistor channel can be formed by a dielectric layer, such as an oxide layer 46. As above, oxide layer 46 can be considered to have an intermediate thickness as compared to the thicknesses of oxide layer 44 and oxide layer 42. A spacer 48 can be provided around the gate structure of top control gate 38, floating gates 40A and 40B, and oxide layers 42, 44, 46. A back, or bottom, control gate 49 can be disposed on a bottom surface 32C of substrate 32. For example, back, or bottom, control gate 49 can reside on back gate oxide layer 32B. Floating gates 40A and 40B can be associated with one side of the channel of the device, and bottom control gate 49 can be associated with an opposite side of the channel of the device.

Second floating gate 40B can be composed of a high work function metal, for example, platinum (Pt), and first floating gate 40A can be composed of a low work function metal, for example, magnesium (Mg). Having a high work function metal for second floating gate 40B separated by a thin oxide layer 44 from a low work function metal for first floating gate 40A can facilitate dynamic memory characteristics of multilayer floating gate FET device 30. For example, such a structure can facilitate rapid charge transfer from first floating gate 40A to second floating gate 40B through the low barrier, which is the result of the low work function metal of first floating gate 40A, for fast dynamic write operation (about 50 ns). The electron back-tunneling from second floating gate 40B to first floating gate 40A through the high barrier, which is the result of the high work function metal of second floating gate 40B, can be relatively slow, enabling improved charge retention and a longer refresh period. It can take about one (1) second until all the charges transfer back to first floating gate 40A such that multilayer floating gate FET device 30 would be back in its initial uncharged state.

For the dynamic memory operation, a low work function metal (e.g., low relative energy to remove an electron), such as TaN, TiN, Al, Ta or Mg, can be chosen for first, or bottom, floating gate 40A to enable rapid charge transfer to second, or top, floating gate 40B. Second floating gate 40B can comprise a high work function metal, such as Pt, Au, or Pd, to reduce the electron back-tunneling rate and improve the charge retention time to enable a longer refresh period.

Thicknesses of the example components of multilayer floating gate FET device 30 can vary depending on the use of device 30 and the materials used. For example, first floating gate 40A and second floating gate 40B can each have a thickness of about 3 nm. Oxide layer 42 can, for example, have a thickness of about 18 nm, while oxide layer 44 between floating gates 40A and 40B can have a thickness of about 3.2 nm and oxide layer 46 between first floating gate 40A and substrate body 32A can have a thickness of about 4.0 nm. As an example, back gate oxide layer 32B can have a thickness of about 1.2 nm. As shown in FIG. 2A, multilayer floating gate MOSFET device 30 can also have a gate length L_{G} that can minimize drain induced barrier lowering (DIBL). For example, gate length L_{G} can be about 16 nm. As above, other lengths L_{G} are contemplated.

Top control gate 38, source region 36, drain region 34, and back gate 49 can comprise the same or different materials. For example, top control gate 38, source region 36, drain region 34, and back gate 49 can comprise Aluminum which has a work function of about 4.1 eV. Top control gate 38 can, for example, have a thickness of about 50 nm, while drain region 34 and source region 36 can have a thickness of about 5 nm and back gate 49 can have a thickness of about 10 nm. In some embodiments, SOI substrate body 32A can be doped with Boron (B) with a concentration of 1.0 e15 cm³ and drain and source regions, or terminals, 34, 36 can be doped with Arsenic (As) with a concentration of about 7.0 e19 cm³. The channel region can be doped with Boron (B) with a concentration of 5.0 e17 cm⁻³.

The embodiment of multilayer floating gate FET device 30 can comprise three top terminals of drain terminal 34, top control gate 38, and source terminal 36, respectively. Back, or bottom, control gate 49 can serve as a fourth terminal that can be connected to a select line for specific applications to provide flexibility in choices of voltages to change the operational state/mode of multilayer floating gate FET device 30. Alternatively, the substrate node can be used as the fourth terminal.

Examples of choices for voltages or voltage envelopes to change the operational state/mode of multilayer floating gate FET device 30 can vary depending on the materials, structures and the widths of the components. For example, multilayer floating gate FET device 30 can have voltages of about 7 Von top control gate 38 and about −2 V on back gate 49 from a select line for 30 μs applied thereto to switch from a non-volatile uncharged to a non-volatile charged state. Additionally and/or alternatively, multilayer floating gate FET device 30 can have voltages of about −7 V on top control gate 38 and about 2 V on back, or bottom, control gate 49 from the select line for 14 μs applied thereto to switch multilayer floating gate FET device 30 back to the non-volatile uncharged state.

When operating as a memory, multilayer floating gate FET device 30 can operate in different manners. As shown in FIG. 2B, multilayer floating gate FET device 30 can operate in a dynamic mode as a dynamic memory with programming a logic one (“1”) with a modest voltage V_{LCG} and short duration to top control gate 38 terminal relative to source terminal 36 and drain terminal 34. For example, a modest voltage V_{LCG} can include about 4 V to about 5 V, while a short duration can include a duration of about 50 ns to about 100 ns. In this manner, a redistribution of charge between first floating gate 40A and second floating gate 40B from one of the floating gates 40A and 40B to the other occurs through the influence of a first electrical field from voltage V_{LCG}. The voltage envelope can be such that the electrical field created is not sufficient to draw up charge from the channel. Thereby, a modest charge C_{D} is placed on floating gates 40A and 40B.

Since charge C_{D} is considered modest, refresh of multilayer floating gate FET device 30 on a periodic basis can be performed to provide charge retention. A logic zero (“0”) is stored by erasing the stored charge and multilayer floating gate FET device 30 can return to an uncharged state. An uncharged multilayer floating gate FET device 30 can, for example, have a threshold voltage V_{T0}, while a dynamically charged device can, for example, have a threshold voltage of about V_{T0}−0.4 V. Additionally, the charge transfer can be similar if the voltage across an entire gate stack GS (which can comprise top control gate 38, oxide layer 42, top floating gate 40B, oxide layer 44, bottom floating gate 40A, oxide layer 46, substrate body 32A, back gate oxide layer 32B, and back gate 49) is equal or approximately equal. For example, for a voltage of about 5 V on top control gate 38 and about 0 V on back gate 49 from the select line, the charge transfer is very similar to the case where top control gate 38 has a voltage of 3 V and the select line provides a voltage of −2 V to back gate 49. The purpose of the select line is to selectively charge multilayer floating gate FET device 30 in both dynamic and non-volatile memory operations. For example, if an entire row of these devices is driven with the same voltage V_{LCG} of 3 V on top control gate 38, then these devices that are to be dynamically charged require a select line voltage of −2 V on back, or bottom, control gate 49, while the other devices that are to maintain the uncharged state require a select line voltage of +2V on back, or bottom, control gate 49.

As shown in FIG. 2C, multilayer floating gate FET device 30 can also operate in a “non-volatile mode” as a non-volatile memory. For example, multilayer floating gate FET device 30 can operate as a non-volatile memory by programming a logic one (“1”) with a higher voltage V_{HCG} and longer time relative to the dynamic memory mode operation described above to top control gate 38 relative to drain terminal 34 and source terminal 36 to place more charge from the channel on floating gates 40A and 40B. Thereby, a larger charge C_{NV} is placed on floating gates 40A and 40B. Multilayer floating gate MOSFET device 30 can be transferred between the two states/modes by applying a set of external biases on top control gate 38 and optionally on back gate 49. Examples of a set of external biases include 9 V on top control gate 38 for 30 μs to transfer to the non-volatile charged state and −9 V on top control gate 38 for 14 μs to transfer back to the non-volatile uncharged state. In this manner, a redistribution of charge between first floating gate 40A and second floating gate 40B with electrons supplied through a channel to first and second floating gates 40A and 40B when under the influence of a second electrical field from voltage V_{HCG} with voltage V_{HCG} being greater than voltage V_{LCG}.

Multilayer floating gate FET device 30 can operate in simultaneous/concurrent states by first programming it with a non-volatile state and then super-imposing a dynamic state onto multilayer floating gate FET device 30. In this mode of operation, multilayer floating gate FET device 30 can be considered to have four (4) “combined states.” The (non-volatile, dynamic) pairing of the states can be represented by the array (“00”, “01”, “10”, “11”), where each state can produce a different threshold voltage for multilayer floating gate FET device 30.

While specific structures are shown in FIGS. 1, 2A, 2B, and 2C for multilayer floating gate FET device 10 and multilayer floating gate FET device 30 that can operate in the manner described above in both a dynamic and non-volatile state, numerous possible configurations for the multilayer floating gate FET devices are contemplated. For example, a planar device with solid floating gates similar to multilayer floating gate FET device 10 shown in FIG. 1 can be provided. As another example, a silicon on insulator (SOI) device, such as multilayer floating gate FET device 30 as shown in FIGS. 2A-2C can permit better scaling, and the introduction of a back gate.

In another example, FIG. 3A shows another embodiment of a multilayer floating gate FET device 50. As with the embodiments above, multilayer floating gate FET device 50 can be a multilayer floating gate MOSFET device. Multilayer floating gate FET device 50 can comprise a substrate 52 on which a drain region or terminal 54 and a source region or terminal 56 can reside. A transistor channel can be formed between drain terminal 54 and source terminal 56 in substrate 52 when a voltage is applied to multilayer floating gate FET device 50. Multilayer floating gate FET device 50 can also comprise a top control gate 58 through which a voltage can be supplied. Multilayer floating gate FET device 50 can comprise a plurality of floating gates, for example, two discontinuous floating gates 60A and 60B that can be separated from top control gate 58 by a dielectric layer, such as a thick oxide layer 62. Discontinuous floating gates 60A and 60B can comprise, as in this embodiment, nanocrystals. First and second nanocrystal floating gates 60A and 60B can be separated from each other by a dielectric layer, such as a thin oxide layer 64. Further, nanocrystal floating gates 60A and 60B can be separated from the portion of substrate 52 in which the transistor channel can be formed by a dielectric layer, such as an oxide layer 66. As above, oxide layer 66 can be considered to have an intermediate thickness as compared to the thicknesses of oxide layer 64 and oxide layer 62. Nanocrystal floating gates 60A and 60B can increase reliability. In such an embodiment as shown in FIG. 3A, less charge transfer can occur, though, especially between the two floating gates. If less charge transfer does occur, programming voltage may need to be changed and the amount of time in the dynamic memory mode may also change.

As described above, many possibilities exist for the multilayer floating gate FET device described herein. The following description provides additional detail and examples. According to the present subject matter, these multilayer floating gate FET devices can provide both one transistor-one capacitor (1T-1C) DRAM and non-volatile memory (NVM) operations. For certain implementations, the multilayer floating gate FET device can be based on a dual-layer nanocrystal floating gate (NCFG) structure and the use of ultra-thin HfO₂ between the top and bottom gates. For example, as illustrated in FIG. 3A, multilayer floating gate FET device 50 can have nanocrystal first and second floating gates 60A and 60B with an ultra-thin oxide layer 64 therebetween of HfO₂. A relatively low control gate voltage (V_{CG}) such as about 4 V to about 5 V, enables very fast charge transfer between nanocrystal floating gates 60A and 60B, which results in a slight threshold voltage shift (ΔV_{T}). The threshold voltage shift (ΔV_{T}) can include a voltage shift in a range of about 0.1 V to about 0.15 V, for example, as appropriate for a given implementation. During the dynamic memory operational mode of the device, the electrons rapidly tunnel back to the source layer until the initial state of the device is reached. In order to maintain the slight ΔV_{T}, a constant refresh voltage pulse can be used. This dynamic memory behavior can therefore be considered similar to a 1T-1C DRAM, which also utilizes a constant refresh due to the charge leakage of its corresponding capacitor.

The non-volatile memory (NVM) operational mode of multilayer floating gate FET device 50 can be exploited by applying a high control gate voltage. An example of a high control gate voltage includes a voltage in a range of about 11 V to about 13 V. Charge transfer takes place between the channel and the nanocrystals, which results in a large ΔV_{T} in the range of about 0.5 V to about 2 V. Substrate 52 can comprise silicon (Si) and the oxide layer 66, which can form the transistor tunnel oxide, can comprise SiO₂. The SiO₂ tunnel oxide can be relatively thick and can have a higher barrier compared to oxide layer 64 of HfO₂ such that charge leakage is reduced and a retention time of about ten (10) years can be possible. As such, the multilayer floating gate FET device 50 can be used as a multi-functional memory device with both 1T-1C DRAM and non-volatile memory characteristics while these two operations can be differentiated by use of the applied control gate voltage as described above.

The multilayer floating gate FET devices of the present subject matter, such as multilayer floating gate FET device 10, multilayer floating gate FET device 30, and multilayer floating gate FET device 50, can be used, for example, in the main memory of a central processing unit (CPU). In such an implementation, these multilayer floating gate FET devices can function similar to a conventional DRAM during the active mode with availability of the enhanced features described herein. When switching to the hibernate mode a voltage pulse such as about 9 V to about 13 V can be used to convert the dynamically stored charge into non-volatile stored charge to save the information in a non-volatile manner. While switching again to the active/dynamic mode, a conversion back to the dynamic charge storage takes place and the main memory is instantly loaded. As an example, load time can include a load time in the range of about 10 ms. Other applications can be found in reconfigurable circuitry. For example, network on chip (NoC) and field programmable gate array (FPGA) applications may use the non-volatile memory (NVM) of these multilayer floating gate MOSFET devices to disconnect a node within the given circuit network. These devices can also exploit the dynamic memory behavior for low overhead, low power and low voltage swing interconnect. An example of the low voltage swing interconnect can include a range of about 0.3 V to about 0.7 V.

Referring again to FIG. 3A, multilayer floating gate FET device 50 can use a dual-layer nanocrystal floating gate (NCFG) structure of nanocrystal first and second floating gates 60A and 60B with a dielectric layer, such as an oxide layer 64 of a HfO₂ insulator, sandwiched therebetween. Control gate 58, source terminal 56 and drain terminal 54 can comprise molybdenum (Mo). The nanocrystals of floating gates 60A and 60B can comprise Palladium (Pd), which can have a relatively high work function in order to prevent charge leakage to the channel and to control gate 58. Oxide layer 62 between control gate 58 and second, or top, floating gate 60B and oxide layer 66 between first, or bottom, floating gate 60A can comprise SiO₂. The conduction band diagram across the Mo—SiO₂—Pd—HfO₂—Pd—SiO₂—Si stack under flat-band condition is shown in FIG. 3B. Within FIG. 3B, the first region on the left represents the Mo layer of control gate 58, followed by the other represented layers (oxide layer 62, top floating gate 60B, oxide layer 64, bottom floating gate 60A, oxide layer 66, and substrate 52) of the Mo—SiO₂—Pd—HfO₂—Pd—SiO₂—Si stack from left to right.

Example geometry parameters and doping profiles for an embodiment of multilayer floating gate FET device 50 device are listed in Table A below. The device can have, for example, a 1 μm depth into the third dimension (i.e., into the page relative to the 2D-schematic model). In addition to the deep potential well in the nanocrystals of the floating gates 60A and 60B, the SiO₂ tunnel oxide layer 66 can be about 4 nm thick in order to achieve a retention time of approximately ten (10) years when multilayer floating gate FET device 50 is used as a non-volatile memory.

Multilayer floating gate MOSFET device 50 can have a gate length L_{G} that can minimize drain induced barrier lowering (DIBL) and can obtain a reasonable amount of nanocrystals for an increase in charge storage capacity. For example, gate length L_{G} can be about 65 nm. The scalability of the described embodiment of multilayer floating gate MOSFET device 50 can be very similar to conventional single-layer nanocrystal floating gate devices depending on the types of materials used in the rest of the device and the structural dimensions of those components used. For example, a gate length L_{G} of about 45 nm can also be tolerated when oxide layer 66 is reduced to about 3.6 nm and still achieve a retention time of ten (10) years when Pd nanocrystals are used. The HfO₂ insulator of oxide layer 64 between top and bottom nanocrystal floating gates 60A and 60B can be ultra-thin, which in addition to the high dielectric constant can result in strong coupling between nanocrystal floating gates 60A and 60B. For the SiO₂ control gate oxide layer 62, a minimal thickness of about 6 nm can be used such that charge transfer between the nanocrystals of floating gates 60A and 60B and control gate 58 can be reduced.

As an example, a tunneling current through control gate oxide layer 62 can be approximately 1×10⁻²⁰ A/μm in the worst case. During the dynamic or non-volatile memory operation, the electron current through oxide layer 64 or oxide layer 66 can be in the range of approximately 1×10⁻⁸ A/μm to about 1×10⁻¹² A/μm. As such, the tunneling current, and thus the charge transfer through oxide layer 62 can be considered very minimal.

The nanocrystals of second, or top, floating gate 60B can be smaller than the nanocrystals of first, or bottom, floating gate 60A so that charge transfer between the two layers of floating gates 60A and 60B can be utilized rather than floating gates 60A and 60B being of similar sizes that may lead to a suppression of charge transfer. It should be noted that if all the nanocrystals on both floating gates 60A and 60B were the same size, a scenario can occur where none of the nanocrystals on first floating gate 60A align with the nanocrystals of second floating gate 60B. As such, the nanocrystals on first, or bottom, floating gate 60A can be bigger to average out the alignment with the nanocrystals in second, or top, floating gate 60B. However, self-alignment of nanocrystals can be utilized as appropriate depending on the implementation.

TABLE A
A parameter list and a doping profile of an example
embodiment of a dual-layer NCFG device.

| Parameter | Value | Region | Material | Doping |
|---|---|---|---|---|
| Channel Length | 65 nm | Substrate | Boron | 5e16 cm ⁻³ |
| Ox₁ (SiO₂) Thickness | 4 nm | Channel | Boron | 5e17 cm ⁻³ |
| Ox₂ (HfO₂) Thickness | 1.5 nm | Source | Arsenic | 1e19 cm ⁻³ |
| Ox₃ (SiO₂) Thickness | 6 nm | Drain | Arsenic | 1e19 cm ⁻³ |
| Top NCs Height | 2 nm | | | |
| Top NCs Length | 3 nm | | | |
| Top NCs Spacing | 3 nm | | | |
| Bottom NCs Height | 3.5 nm | | | |
| Bottom NCs Length | 5 nm | | | |
| Bottom NCs Spacing | 5 nm | | | |

In some embodiments, a vertical multilayer floating gate FET device can be provided with the gate stack on one or both side walls. For example, as shown in FIG. 4, a cross-sectional view of a further embodiment of a multilayer floating gate FET device generally designated 70 is provided, which can be a tri-gate finFET device. Multilayer floating gate FET device 70 can be a multilayer floating gate MOSFET device. Multilayer floating gate FET device 70 can comprise a substrate 72 which can comprise a fin 72A that can be oriented or positioned vertically. Fin 72A of substrate 72 can have sidewalls 72A₁, 72A₂, 72A₃. A drain region or terminal 74 and a source region or terminal 76 can reside in substrate 72. A transistor channel can be formed between drain terminal 74 and source terminal 76 in substrate 72 when a voltage is applied to multilayer floating gate FET device 70. Drain terminal 74 and source terminal 76 can be located at different positions on substrate 72. For example, drain terminal 74 and source terminal 76 can be located on either side of fin 72A as shown in FIG. 4 or can be located at opposing ends of fin 72A (not shown). As stated above, it is understood that drain terminal 74 and source terminal 76 can be reversed so that drain terminal 74 can serve as the source terminal and source terminal 76 can be used as the drain terminal.

Multilayer floating gate FET device 70 can also comprise a top control gate 78 through which a voltage can be supplied. Multilayer floating gate FET device 70 can comprise a plurality of floating gates, for example, two floating gates 80A and 80B that can be separated from top control gate 78 by a dielectric layer, such as a thick oxide layer 82. Floating gates 80A and 80B can be separated from each other by a dielectric layer, such as a thin oxide layer 84. Further, floating gates 80A and 80B can be separated from the portion of substrate 72 in which the transistor channel can be formed by a dielectric layer, such as an oxide layer 86. In some embodiments, oxide layer 86 can be considered to have an intermediate thickness as compared to the thicknesses of oxide layer 84 and oxide layer 82. Oxide layer 86 can extend along sidewalls 72A₁, 72A₂, 72A₃. Further, floating gates 80A and 80B can extend along a portion of at least one of sidewalls 72A₁, 72A₂, 72A₃ with thin oxide layer 84 between floating gates 80A and 80B. For example, as shown in FIG. 4, floating gates 80A and 80B can extend along at least a portion of each sidewall 72A₁, 72A₂, 72A₃ to facilitate the creation of a tri-gate structure. In this manner, second floating gate 80B, oxide layer 84, first floating gate 80A and oxide layer 82 form at least a portion of a gate stack GS and the gate stack GS is positioned on a portion of at least one of side walls 72A₁, 72A₂, 72A₃ of substrate 72.

As shown in FIG. 4, control gate 78 can be positioned on oxide layer 82 only on a top portion 70A of device 70. In this manner, oxide layer 82 only needs to be thick only in the top portion 70A of multilayer floating gate FET device 70 and oxide layer 82 can be thinner on side portions 70B of multilayer floating gate FET device 70. In this manner, the footprint of each multilayer floating gate FET device 70 can be smaller and the density of multilayer floating gate FET devices 70 can be increased.

As shown in FIG. 4, a voltage V_{CG} can be applied to control gate 78 and a channel CH can be created through substrate 72 including fin 72A. As above, depending on the level and duration of voltage V_{CG}, multilayer floating gate FET device 70 can operate as a dynamic memory element in response to a first voltage and as a non-volatile memory element in response to a second voltage or voltage envelope that is higher than the first voltage or voltage envelope.

In another example embodiment shown in a cross-sectional view in FIG. 5, a different multilayer floating gate FET device generally designated 90, which can also be considered tri-gate finFET device is provided. As in the example above, multilayer floating gate FET device 90 can comprise a substrate 92 which can comprise a fin 92A that can be oriented or positioned vertically. Fin 92A of substrate 92 can have sidewalls 92A₁, 92A₂, 92A₃. A drain terminal 94 and a source terminal 96 are positioned in substrate 92 which can occur in different manners as suggested above. A top control gate 98 through which a voltage can be supplied can be positioned on a top portion 90A of multilayer floating gate FET device 90. As in the example embodiment described above, multilayer floating gate FET device 90 can comprise a plurality of floating gates, for example, two floating gates 100A and 100B that can be separated from top control gate 98 by a dielectric layer, such as a thick oxide layer 102. Floating gates 100A and 100B can be separated from each other by a dielectric layer, such as a thin oxide layer 104. Further, floating gates 100A and 100B can be separated from the portion of substrate 92 in which the transistor channel can be formed by a dielectric layer, such as an oxide layer 106 having an intermediate thickness as compared to the thicknesses of oxide layer 104 and oxide layer 102.

Floating gates 100A and 100B and oxide layers 104 and 106 can extend along at least a portion of each sidewall 92A₁, 92A₂, to facilitate the creation of a tri-gate structure. A third gate 108 can be positioned adjacent sidewall 92A₃ of fin 92A of substrate 92. Third gate 108 can be a programming gate used to read and write to multilayer floating gate FET device 90. As with the embodiment shown in FIG. 4, control gate 98 can, for example, be positioned above oxide layer 102 only on a top portion 90A of device 90. In this manner, oxide layer 102 only needs to be thick in the top portion 90A of multilayer floating gate FET device 90 and oxide layer 102 can be thinner on side portions 90B₁, 90B₂ of multilayer floating gate FET device 90.

In a further embodiment, a circular multilayer floating gate FET device (not shown) with a surround gate stack can be provided. Additionally and/or alternatively, two multilayer floating gate FET devices can be connected serially with one device optimized for write and then biased into a low leakage state, and another device optimized for read.

A simulation of a device similar to multilayer floating gate FET device 50 shown in FIG. 3A was tested in Sentaurus TCAD. Direct tunneling (DT), Fowler-Nordheim tunneling (FNT) and hot carrier injection (HCl) were enabled for each insulator during the simulations of the device with its source and drain grounded. Based on the simulation, the carrier transport through the dielectric layer between the floating gates similar to oxide layer 64 between floating gates 60A and 60B shown in FIG. 3A is mainly due to uniform DT. Additionally, the carrier transport through the dielectric layer between the first floating gate and the channel region of the substrate similar to oxide layer 66 between first floating gate 60A and substrate 52 shown in FIG. 3A is mainly due to uniform FNT of electrons. It is noted that holes play a minimal role in the charge transfer because they are heavy relative to electrons and the barrier in the valence band is relatively high. HCl was found to have virtually no impact on the device for the voltages simulated as it is highly localized at the drain and/or source terminal and may therefore be considered inapplicable for uniform tunneling implementations. Further description of simulated tests is provided below. As a reference, the embodiment shown in FIG. 3A is used as an example embodiment of the embodiment simulated.

### Simulated Tests

### Dynamic Memory Behavior

A short and low voltage pulse of about 10 ns and about 4 V was applied in a simulation to a control gate similar to a control gate 58 to analyze fast electron tunneling in a ultra-thin and low barrier HfO₂ insulator of oxide layer 64.

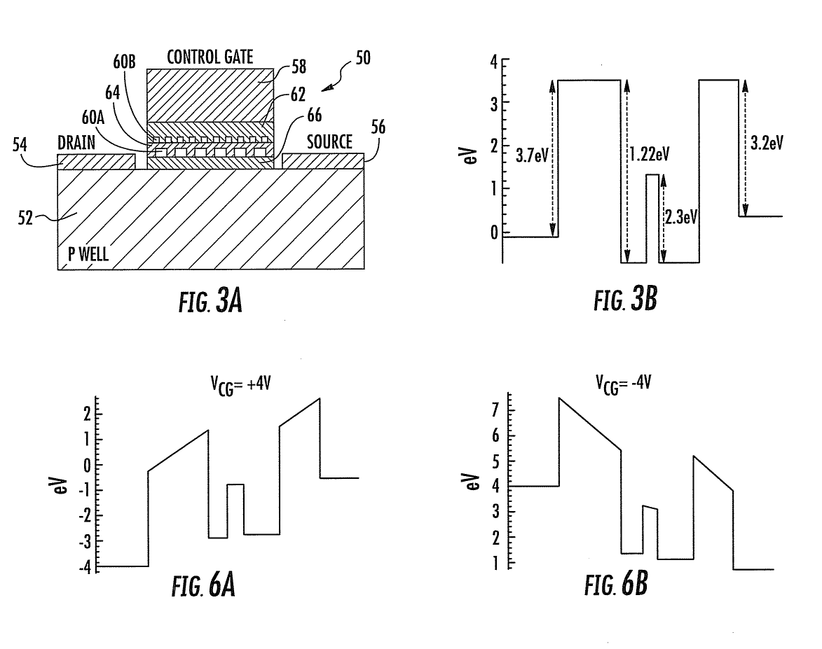

FIGS. 6A and 6B illustrate conduction band diagrams of a multilayer floating gate FET device, similar to multilayer floating gate FET device 50, under simulation during an applied V_{CG} of 4 V and −4 V, respectively. As with FIG. 3B above, the first region on the left represents the Mo layer of control gate 58, followed by the other represented layers (oxide layer 62, top floating gate 60B, oxide layer 64, bottom floating gate 60A, oxide layer 66, and substrate 52) of the Mo—SiO₂—Pd—HfO₂—Pd—SiO₂—Si stack from left to right.

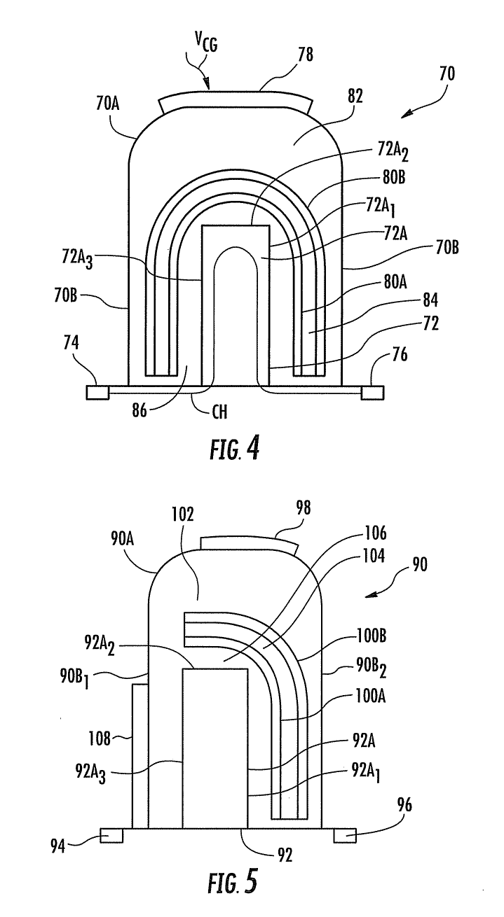

The results of the simulation represent one layer being negatively charged due to electron overshoot, while the other adjacent layer is being positively charged due to electron loss, thus shifting ΔV_{T} slightly as shown in FIGS. 7A and 7B. For example, if the applied gate voltage is positive, the voltage in the bottom layer can increase due to electron loss and a negative ΔV_{T} is obtained for Vg=+4 V in FIGS. 7A and 7B. Analogously, if the applied gate voltage is negative, the voltage in the bottom layer decreases due to electron overshoot, which results in a positive ΔV_{T} for Vg=−4 V in FIGS. 7A and 7B. Therefore, first, or bottom, floating gate 60A can be used to mainly determine the current-voltage (I-V) characteristics of the multilayer floating gate FET device 50 because first floating gate 60A is closest to the channel. The difference of the two shifts Δ(ΔV_{T}) was found within the simulation to be 223 mV. The simulations have shown that electron tunneling through the tunnel oxide layer 66 or control gate oxide layer 62 does not occur as the applied voltage pulses are too low and too short.

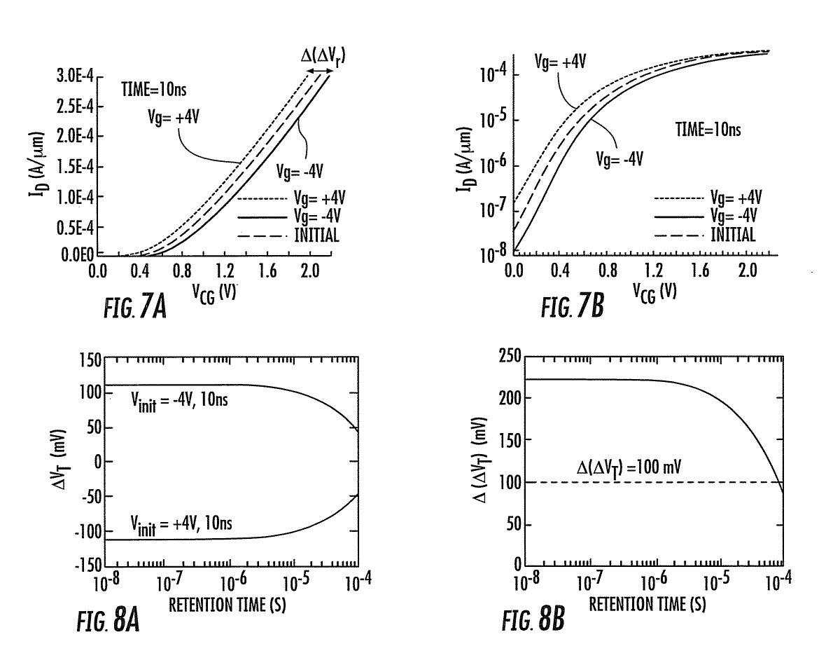

Once multilayer floating gate FET device 50 switches to the retention mode, the electron back-tunneling from negatively to positively charged layer can occur relatively rapidly. The results in the retention time of the dynamic charge storage are shown in FIG. 8A when no voltage is applied on the control gate. The Δ(ΔV_{T}) can be dependent on the types of material used and the thicknesses of those materials. For example, in FIG. 8B, it can be observed that, in order to keep Δ(ΔV_{T}) above 100 mV, a refresh of the multilayer floating gate MOSFET device can be performed at least about every 80 μs. An oxide layer of HfO₂ instead of HfSiO, which has a lower conduction band barrier, between the floating gates can provide a lower barrier. To refresh the device, another voltage pulse of ±4 V for 10 ns is not required. As simulated, a duration of about 7 ns to about 8 ns can be sufficient to obtain the original Δ(ΔV_{T}) of 223 mV.

### Simulated Tests

### Non-Volatile Memory Behavior

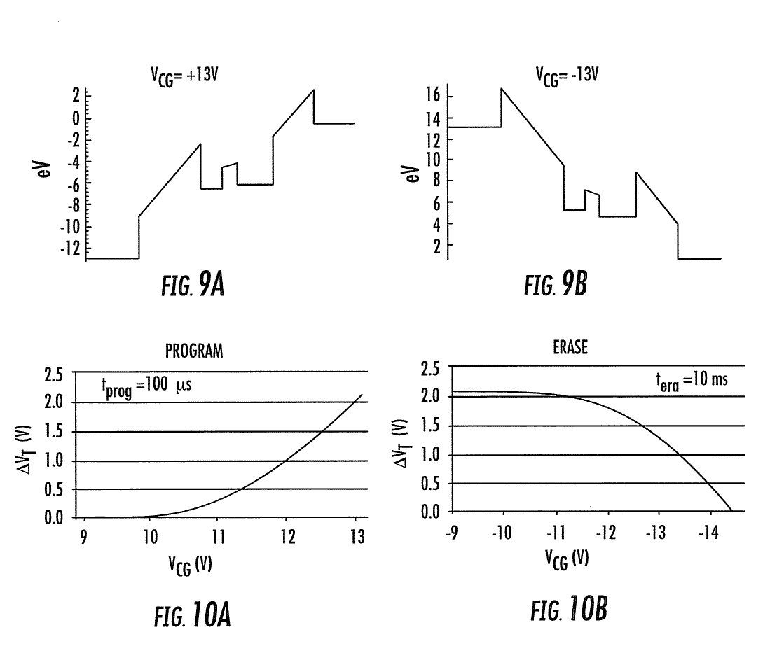

A simulation of the same multilayer floating gate FET device using higher and longer voltage pulses to simulate the device being used as a non-volatile memory was also conducted. A relatively high and long voltage pulse, such as for example a voltage pulse of about 13 volts and about 100 μs duration, can be applied to a device similar to multilayer floating gate FET device 50. These pulses can cause electrons to tunnel between the channel and the nanocrystals of floating gates similar to floating gates 60A and 60B. The band diagrams of programming and erasing a device similar to multilayer floating gate MOSFET device 50 performed by applying ±13 V to the device are shown in FIGS. 9A and 9B, respectively. As with FIG. 6B above, the first region on the left represents the Mo layer of control gate 58, followed by the other represented layers (oxide layer 62, top floating gate 60B, oxide layer 64, bottom floating gate 60A, oxide layer 66, and substrate 52) of the Mo—SiO₂—Pd—HfO₂—Pd—SiO₂—Si stack from left to right. As can be seen from FIG. 9A, the voltage drop across an oxide layer of the HfO₂ insulator similar to oxide layer 64 (see FIG. 3A) is relatively small compared to the voltage drop across the oxide layers of the SiO₂ insulators similar to oxide layers 62, 66 (see FIG. 3A). Thus, the programming and erasing of multilayer floating gate MOSFET device 50 for a NVM application can be similar to a conventional single-layer nanocrystal floating gate device with equivalent tunnel and control gate oxide layer thickness.

In FIG. 10A, the ΔV_{T} is plotted for different V_{CG} pulses for programming the device for a time period of 100 μs and in FIG. 10B for erasing the device for 10 ms. While programming the device, the electrons from the channel tunnel first to the nanocrystals of the first, or bottom, floating gate similar to first, or bottom, floating gate 60A, which can then tunnel further to the second, or top, floating gate similar to second, or top, floating gate 60B. Immediately after the applied voltage pulse is removed, the electrons will partially tunnel back to the bottom layer and stay there until a voltage balance in both layers is reached. This phenomenon has been shown within simulations, such that after the initial voltage pulse a slight change in ΔV_{T} takes place in the first few microseconds of the NVM operational mode, but then ΔV_{T} stays constant. Charge leakage to the channel may be prevented due to a sufficiently thick tunnel oxide layer. In order to erase the device, a relatively high and long negative voltage pulse may be applied on the control gate. Erasing the device is more difficult than programming because the electrons face a higher barrier at the interface between Pd and SiO₂ layers than at the interface between Si and SiO₂ layers.

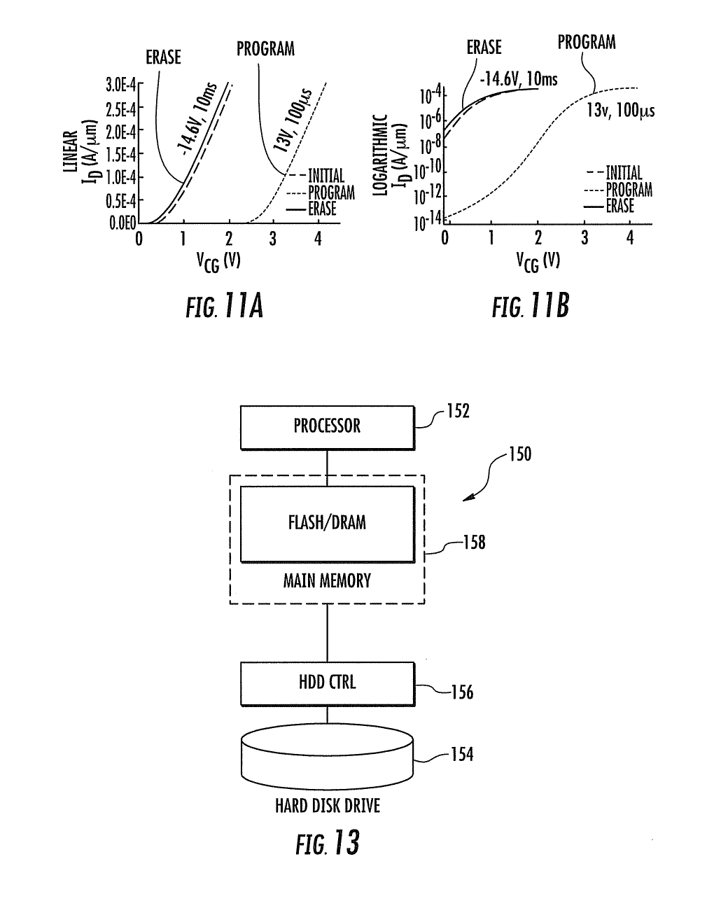

FIGS. 11A and 11B show a plot of the drain current in a linear and logarithmic scale, respectively. First, the drain current is illustrated for an initially uncharged device (dashed line). Then, the device, similar to multilayer floating gate FET device 50 (FIG. 3A) is being programmed (labeled “program”) such that a ΔV_{T} of 2 V is obtained, and lastly the programmed device is being erased (labeled “erase”) resulting in a slightly negative ΔV_{T}. In addition, it can be seen from FIGS. 11A and 11B that the off current of the programmed device is less than 1 pA under these simulation conditions.

It has been observed by simulation results that a device similar to the multilayer floating gate FET device 50 includes both 1T-1C DRAM and NCFG device memory behavior, which are differentiated by and controlled via the applied voltage. These behaviors may therefore be used for multi-functional memory applications. The following description describes possible applications that may benefit from the use of the device described above. Table B summarizes the simulation results described above.

TABLE B
Dynamic and static memory operation of the designed
discontinuous dual-layer floating gate device.

| | Voltage | | |
|---|---|---|---|
| Operation | Envelope | Voltage Shift | Retention |
| Dynamic | 10 ns, ±4 V | ΔV_{T} = ±0.11 V | Δ(Δ V_{T}) → 0.1 V in 80 μs |
| Non-volatile | 100 μs, 13 V | ΔV_{T} = 2 V | 10 years |

As described above, the device may be integrated in various applications such as main memory, network-on-chip platforms, field programmable gate arrays and other applications where a mix of small and large ΔV_{T} is useful.

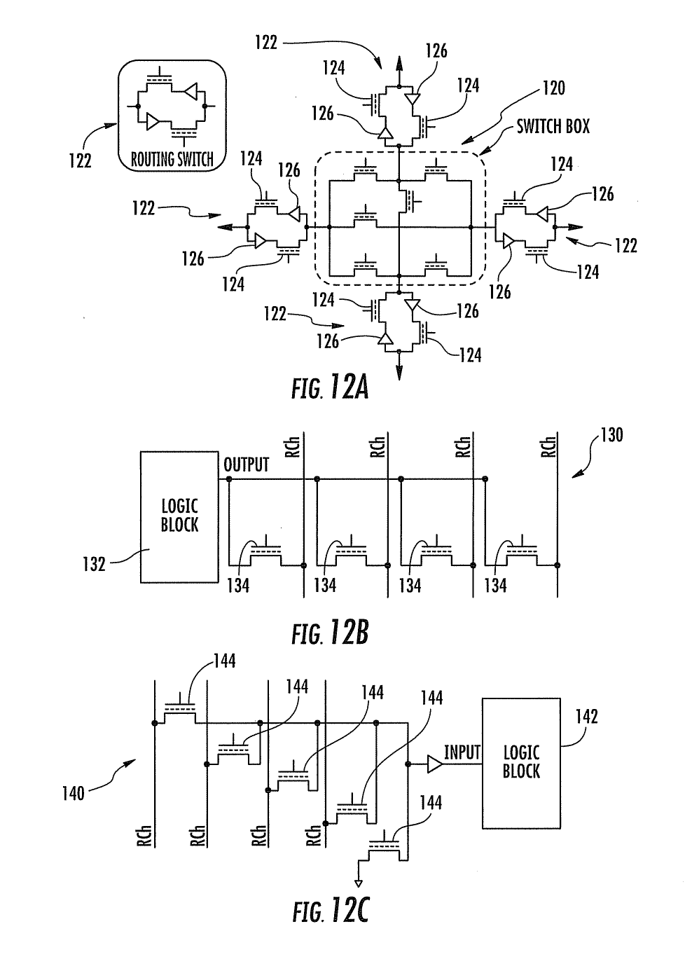

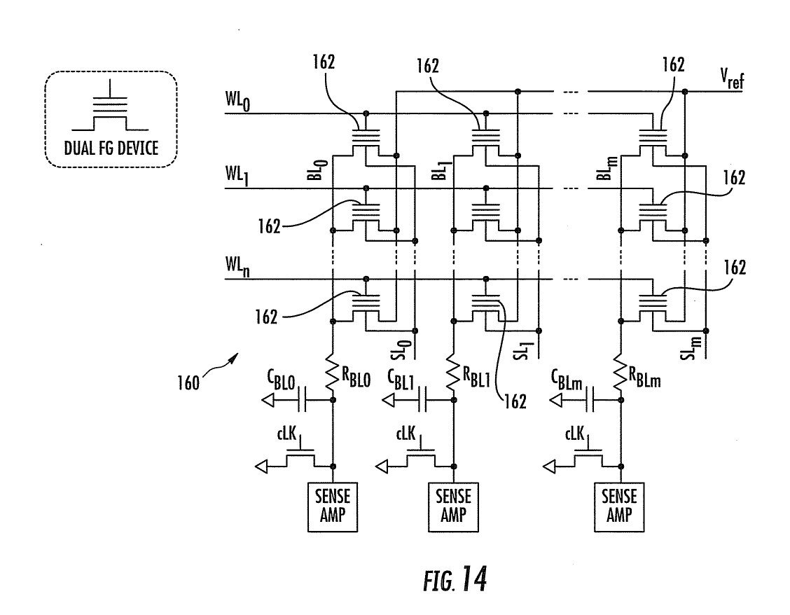

New circuit topologies for the interconnect in an energy efficient field programmable gate array (FPGA) with bidirectional wiring can be created using the multilayer floating gate FET devices described herein. Examples are shown in FIGS. 12A, 12B, and 12C. FIG. 12A shows a schematic switch box generally designated 120 and routing switches 122. Each routing switch 122 can comprise two multilayer floating gate FET devices 124 and two buffers 126. FIG. 12B shows an output connection generally designated 130 of a logic block 132 in which multilayer floating gate FET devices 134 can be used as switches for routing channels RCh. FIG. 12C shows an input connection generally designated 140 of a logic block 142 in which multilayer floating gate FET devices 144 can be used as switches for routing channels RCh.

The FPGA architecture can also be improved based upon the multilayer floating gate FET devices described herein. A new interconnect architecture can be implemented by using multilayer floating gate FET devices described herein as programmable elements to reduce power consumption relative to conventional technologies. The multilayer floating gate FET devices described herein can further improve FPGA technology by using the NVM behavior of the device for the interconnect. Furthermore, by exploiting the dynamic memory behavior, the multilayer floating gate FET devices described herein can be used for the look-up tables (LUTs) in the logic blocks to support fast switching with a low voltage swing, and thus further reduce power consumption.

Certain storage systems in a CPU environment mix DRAM and hard drive, which suffer from slow data transfer. In addition, DRAM consumes a large portion of overall system power. Recently, a hybrid main memory has been introduced, which consists of a smaller first-level DRAM augmented by a second-level flash. The flash consists of continuous floating gate devices, which consume orders of magnitude less idle power than DRAM. In addition, integrating flash memory into the conventional system-level memory hierarchy enables quick warm up of file buffer caches. This DRAM/flash memory system is proposed for low power web servers, and it is already in commercial use, e.g., for modern cell phones and digital cameras. The same concept can be used where the data is stored in the volatile DRAM and then gradually transmitted to the non-volatile flash. Once the information is stored in the flash, it can be loaded back to the DRAM during boot time. The benefits of the hybrid main memory compared to a conventional single DRAM main memory are less loading time, smaller DRAM, and especially orders of magnitude less idle power consumption.

FIG. 13 illustrates an embodiment of CPU unit generally designated 150 that includes a processor 152, hard disk drive 154 and a HDD control 156. Further, a main memory 158 of CPU 150 can comprise multilayer floating gate FET devices described herein similar to multilayer floating gate FET devices 10, 30, 50, 70, and/or 90 described above instead of conventional flash and DRAM memories. For example, an embodiment of a main memory generally designated 160 using multilayer floating gate FET devices 162 as described herein is shown in FIG. 14.

The multilayer floating gate FET devices described herein may improve main memory 158 (see FIGS. 13) and 160 (see FIG. 14) beyond existing hybrid memory architectures. The simulation results of the dynamic charge storage of the device may be considered comparable to those of a 1T-1C DRAM. Fabrication costs of the multilayer floating gate FET devices described herein may be significantly reduced compared to conventional DRAM. In addition to cost, the absence of a capacitor within the device described herein may allow higher on-chip density. The multilayer floating gate FET devices described herein may further be manufactured more densely than flash memory due to better scalability compared to continuous floating gate devices. Furthermore, the soft error bit rate may be statistically low because the sense amplifier needs to detect a relatively large voltage swing of 200-223 mV. The write time of the device may be as low as 10 ns based upon the specific implementation. The short refresh period may be on the order of 80 μs and the write voltage on the order of 4 V. In order to extend the retention time of the device, the HfO₂ layer may be fabricated to be thicker and/or a solid or a nanocrystal metal with a higher work function may be used.

As described above, the multilayer floating gate FET devices described herein can also utilize non-volatile charge storage in addition to dynamic memory behavior. During active mode, the memory can exhibit dynamic memory behavior. The operational clock frequency can be increased relative to conventional designs due to the relatively short write time and relatively short refresh time. When the power is turned off, a high voltage pulse or voltage envelope can be used to save the information due to the non-volatile charge storage mode of the device. A controller can be used to provide the multilayer floating gate FET devices with both low and high voltages for the operations described herein. While the system is booting up, the multilayer floating gate FET devices described herein can be converted back from non-volatile to dynamic memory operation and the main memory can be rapidly loaded with the stored non-volatile value. No time consuming data transfer between the main memory and the hard disk or flash is required. In addition, as the main memory size increases, unused memory cells do not need to be refreshed and can be fully programmed, resulting in very low leakage current on the order of 1 pA, as appropriate for a given implementation, and can therefore reduce power consumption. These potential benefits make the multilayer floating gate FET devices described herein suitable for high speed and very dense main memory where a refresh period of 80 μs is acceptable.

Another use or application for the multilayer floating gate FET devices described herein can be a network-on chip (NoC) platform with a goal of achieving lower power consumption in such an implementation. In electronic NoCs, a message can be buffered, regenerated, and then transmitted on the interrouter links to its destination. Furthermore, the switching and regenerating elements in CMOS can consume dynamic power that grows with the data rate. By separating the signaling control from the data transmission, the device electronics can implement the signaling control path, while maintaining a transparent photonic data path. The device also can buffer data at the source where electronic memory is cheap and abundant. Buffering messages in a photonic network can be challenging because photonic storage elements are not available. In a hybrid network, a setup message, which contains destination and control information, can be first routed on the electronic control network. It can reserve the photonic switches along the path for the photonic message. Once the data path is acquired, the photonic message can be transmitted. Thus, the hybrid network can resemble a circuit-switched network with high speed and low power data transmission.

The multilayer floating gate FET devices described herein can be integrated in the routers of the control network and utilize the short write time and low voltage swing (and thus low power) of the device to improve both speed and power consumption within such an implementation. In addition, a just-in-time (JIT) setup and tear-down scheme can be used to reconfigure such a network. Hybrid NoC can be conventionally considered efficient for data-bursts which are much longer than the setup time due to round trip delays for setup. In JIT signaling, the futures of circuit-switching can be combined with those of packet-switching in order to minimize the setup time, and maximize the cross-connect bandwidth efficiency. The setup message can be sent from the source and travel hop-by-hop through the network. Each time it reaches a switch, the switch can reserve the wavelength on the output port, establish a cross-connect, and forward the message to the next hop. When the destination receives the setup message, it responds with a connect message that can be sent back to the source. Meanwhile, the data-burst can be sent and can arrive at the network elements just in time after a cross-connect has been made at each switch along the path.

A hybrid NoC architecture that utilizes JIT signaling can benefit from using the multilayer floating gate FET devices described herein as a switching element in the same manner as without JIT signaling. The information in the setup message can determine the polarity of the short voltage pulse that can be applied on the device. The resulting slight positive or negative ΔV_{T} can turn the photonic switch on or off. Unused switches can be virtually disconnected from the network by converting the multilayer floating gate FET devices described herein in a fully programmed state by applying a high voltage pulse in order to save more power.

The multilayer floating gate FET devices described herein can be formed in different manners depending on the materials used, the design criteria and contemplated structure and the implementations expected for the devices. The deposition of materials and layers can be performed using conventional techniques. A method of forming a multilayer floating gate FET device can comprise providing a substrate having a source region, a drain region, and a channel region disposed between the source region and the drain region. A channel can be formed in the channel region of the substrate of the multilayer floating gate FET device once constructed when an appropriate voltage is applied to the device. A first dielectric layer can be disposed on the substrate adjacent the channel region. A layer of a conductive material that serves as a first floating gate can be disposed on the first dielectric layer. A second dielectric layer can be disposed on the conductive material that serves as the first floating gate. A second layer of a conductive material that serves as a second floating gate can be disposed on the second dielectric layer. The second dielectric layer between the first floating gate and the second floating gate can be of a thickness and of a type of material that permits a redistribution of charge between the first floating gate and the second floating gate from one of the floating gates to the other when under the influence of a first electrical field from a first voltage. Generally, as described above, the second dielectric layer can be thin, for example, thinner than the first dielectric layer that is disposed between the substrate and the first layer of conductive material that serves as the first floating gate.

A third dielectric layer can be disposed on the conductive material that serves as a second floating gate. This third dielectric layer can be much thicker the either of the first dielectric layer or the second dielectric layer as described in detail above. A third layer of the conductive material that serves as a control gate can be disposed on the third dielectric layer.

In some embodiments, the conductive material of the first floating gate can comprise a low work function metal. For example, the low work function metal can comprise a metal such as tantalum nitride (TaN), titanium nitride (TiN), aluminum (Al), tantalum (Ta) or magnesium (Mg). Similarly, in some embodiments, the second floating gate comprises a high work function metal. For example, the high work function metal can comprise a metal such as platinum (Pt), gold (Au), or palladium (Pd). As described above, depending on the implementation of the device, different layers for conductive material can be solid or discontinuous (i.e., discrete). For example, in some embodiments, the layer of the conductive material that serves as the first floating gate can comprise a solid layer and the layer of the conductive material that serves the second floating gate can comprise a solid layer. Alternatively, in some embodiments, the layer of the conductive material that serves the first floating gate can comprise a discontinuous layer and the layer of the conductive material that serves the second floating gate can comprise a discontinuous layer. For example, the discontinuous layers that serve as the first floating gate and the second floating gate can comprise nanocrystals.

As described in detail above, in some embodiments, the second dielectric layer can comprise a high-k insulator material, such as hafnium oxide (HfO₂), aluminum oxide (Al₂O₃), zirconium oxide (ZrO₂), hafnium aluminate (HfAlO), and hafnium silicate (HfSiO). In some embodiments, the first dielectric layer comprises a low-k insulator material.

It will be understood that various details of the presently disclosed subject matter may be changed without departing from the scope of the presently disclosed subject matter. Furthermore, the foregoing description is for the purpose of illustration only, and not for the purpose of limitation.

What is claimed is:

1. A multilayer floating gate field-effect transistor (FET) device, comprising:
a first floating gate separated via a first dielectric layer from a channel of the device;
a second floating gate separated via a second dielectric layer from the first floating gate; and
the second dielectric layer between the first floating gate and the second floating gate permitting a redistribution of charge between the first floating gate and the second floating gate from one of the floating gates to the other when under the influence of a first electrical field from a first voltage.

2. The multilayer floating gate FET device of claim 1, further comprising:
a third dielectric layer that separates the second floating gate from a control gate, the control gate capable of having the first voltage applied thereto.

3. The multilayer floating gate FET device of claim 2, wherein the control gate is configured for receiving a second voltage applied thereto that is greater than the first voltage for the second voltage to generate a second electrical field that causes a redistribution of charge between the first floating gate and the second floating gate with electrons supplied through a channel.

4. The multilayer floating gate FET device of claim 3, wherein the first floating gate and the second floating gate are operable as a dynamic memory element in response to the first voltage and as a non-volatile memory element in response to the second voltage.

5. The multilayer floating gate FET device of claim 1, wherein the first floating gate comprises a low work function metal.

6. The multilayer floating gate FET device of claim 5, wherein the low work function metal comprises a metal selected from the group consisting of tantalum nitride (TaN), titanium nitride (TiN), aluminum (Al), tantalum (Ta) and magnesium (Mg).

7. The multilayer floating gate FET device of claim 1, wherein the second floating gate comprises a high work function metal.

8. The multilayer floating gate FET device of claim 7, wherein the high work function metal comprises a metal selected from the group consisting of platinum (Pt), gold (Au), and palladium (Pd).

9. The multilayer floating gate FET device of claim 1, wherein the first floating gate comprises a solid floating gate and the second floating gate comprises a solid floating gate.

10. The multilayer floating gate FET device of claim 1, wherein the first floating gate comprises a discontinuous floating gate and the second floating gate comprises a discontinuous floating gate.

11. The multilayer floating gate FET device of claim 10, wherein the discontinuous floating gates comprise nanocrystals.

12. The multilayer floating gate FET device of claim 1, wherein the first floating gate and the second floating gate are associated with one side of the channel of the device, and a bottom control gate is associated with an opposite side of the channel of the device.

13. The multilayer floating gate FET device of claim 1, wherein the second dielectric layer between the first floating gate and the second floating gate comprises a high-k insulator material.

14. The multilayer floating gate FET device of claim 1, wherein the first dielectric layer comprises a low-k insulator material.

15. The multilayer floating gate FET device of claim 1, wherein the second dielectric layer between the first floating gate and the second floating gate comprises a material selected from the group consisting of hafnium oxide (HfO₂), aluminum oxide (Al₂O₃), zirconium oxide (ZrO₂), hafnium aluminate (HfAlO), and hafnium silicate (HfSiO).

16. The multilayer floating gate FET device of claim 1, wherein the second dielectric layer between the first floating gate and the second floating gate comprises a HfO₂ insulator.

17. The multilayer floating gate FET device of claim 1, further comprising a substrate on which the first dielectric layer is disposed and the first dielectric layer, the first floating gate, second dielectric layer and the second floating gate form at least a portion of a gate stack.

18. The multilayer floating gate FET device of claim 17, wherein the substrate extends vertically with at least two side walls and the gate stack is positioned on a portion of at least one of the side walls of the substrate.

19. The multilayer floating gate FET device of claim 18, wherein the gate stack is positioned on a portion of at least two of the side walls of the substrate.

20. The multilayer floating gate FET device of claim 1, wherein the second dielectric layer between the first floating gate and the second floating gate permits a redistribution of charge between the first floating gate and the second floating gate with electrons supplied through a channel to the first floating gate and the second floating gate when under the influence of a second electrical field from a second voltage with the second voltage being greater than the first voltage.

21. The multilayer floating gate FET device of claim 20, wherein the first floating gate and the second floating gate operable as a dynamic memory element in response to the first voltage and as a non-volatile memory element in response to the second voltage.

22. A multilayer floating gate field-effect transistor (FET) device, comprising:
a first floating gate separated via a first dielectric layer from a channel of the device; and
a second floating gate separated via a second dielectric layer from the first floating gate, the first floating gate and the second floating gate being operable as a dynamic memory element in response to a first voltage envelope and as a non-volatile memory element in response to a second voltage envelope.

23. The multilayer floating gate FET device of claim 22, further comprising:
a third dielectric layer that separates the second floating gate from a control gate, wherein the control gate applies the first voltage envelope and the second voltage envelope.

24. The multilayer floating gate FET device of claim 22, wherein the first floating gate comprises a low work function metal.

25. The multilayer floating gate FET device of claim 24, wherein the low work function metal comprises a metal selected from the group consisting of tantalum nitride (TaN), titanium nitride (TIN), aluminum (Al), tantalum (Ta) and magnesium (Mg).

26. The multilayer floating gate FET device of claim 22, wherein the second floating gate comprises a high work function metal.

27. The multilayer floating gate FET device of claim 26, wherein the high work function metal comprises a metal selected from the group consisting of platinum (Pt), gold (Au), and palladium (Pd).

28. The multilayer floating gate FET device of claim 22, wherein the first floating gate comprises a solid floating gate and the second floating gate comprises a solid floating gate.

29. The multilayer floating gate FET device of claim 22, wherein the first floating gate comprises a discontinuous floating gate that comprises nanocrystals and the second floating gate comprises a discontinuous floating gate that comprises nanocrystals.

30. The multilayer floating gate FET device of claim 22, wherein the first floating gate and the second floating gate are associated with one side of the channel of the device, and a bottom control gate is associated with an opposite side of the channel of the device.

31. The multilayer floating gate FET device of claim 22, wherein the second dielectric layer between the first floating gate and the second floating gate comprises a high-k insulator material.

32. The multilayer floating gate FET device of claim 31, wherein the first dielectric layer comprises a low-k insulator material.

33. The multilayer floating gate FET device of claim 22, wherein the second dielectric layer between the first floating gate and the second floating gate comprises a material selected from the group consisting of hafnium oxide (HfO₂), aluminum oxide (Al₂O₃), zirconium oxide (ZrO₂), hafnium aluminate (HfAJO), and hafnium silicate (HfSiO).

34. The multilayer floating gate FET device of claim 22, wherein the second dielectric layer between the first floating gate and the second floating gate comprises a HfO₂ insulator.

35. A method of forming a multilayer floating gate field-effect transistor (FET) device, comprising:
providing a substrate having a source region, a drain region, and a channel region disposed between the source region and the drain region and in which a channel is formable;
disposing a first dielectric layer on the substrate adjacent the channel region;
disposing a layer of a conductive material that serves as a first floating gate on the first dielectric layer;
disposing a second dielectric layer on the conductive material that serves as the first floating gate; and
disposing a second layer of a conductive material that serves as a second floating gate on the second dielectric layer, such that the second dielectric layer between the first floating gate and the second floating gate permits a redistribution of charge between the first floating gate and the second floating gate from one of the floating gates to the other when under the influence of a first electrical field from a first voltage.

36. The method of claim 35, further comprising disposing a third dielectric layer on the conductive material that serves as a second floating gate and disposing a third layer of the conductive material that serves as a control gate on the third dielectric layer.

37. The method of claim 35, wherein the conductive material of the first floating gate comprises a low work function metal.

38. The method of claim 37, wherein the low work function metal comprises a metal selected from the group consisting of tantalum nitride (TaN), titanium nitride (TiN), aluminum (Al), tantalum (Ta) and magnesium (Mg).

39. The method of claim 35, wherein the second floating gate comprises a high work function metal.

40. The method of claim 39, wherein the high work function metal comprises a metal selected from the group consisting of platinum (Pt), gold (Au), and palladium (Pd).

41. The method of claim 35, wherein the layer of the conductive material that serves as the first floating gate comprises a solid layer and the layer of the conductive material that serves the second floating gate comprises a solid layer.

42. The method of claim 35, wherein the layer of the conductive material that serves the first floating gate comprises a discontinuous layer and the layer of the conductive material that serves the second floating gate comprises a discontinuous layer.

43. The method of claim 42, wherein the discontinuous layers 100 comprise nanocrystals.

44. The method of claim 35, wherein the second dielectric layer comprises a high-k insulator material.

45. The method of claim 35, wherein the first dielectric layer comprises a low-k insulator material.

46. The method of claim 35, wherein the second dielectric layer comprises a material selected from the group consisting of hafnium oxide (HfO₂), aluminum oxide (Al₂O₃), zirconium oxide (ZrO₂), hafnium aluminate (HfAlO), and hafnium silicate (HfSiO).

47. The method of claim 35, wherein the second dielectric layer comprises a HfO₂ insulator.
